(19) United States
(12) Patent Application Publication
(10) Pub. No.: US 2012/0241954 A1
(43) Pub. Date: Sep. 27, 2012

(54) Unpackaged and packaged IC stacked in a system-in-package module

(75) Inventors: Robert W. Warren, Newport Beach, CA (US); Nic Rossi, Hennessy (HK)

(73) Assignee: CONEXANT SYSTEMS, INC., NEWPORT BEACH, CA (US)

(21) Appl. No.: 13/065,620

(22) Filed: Mar. 24, 2011

(51) Int. Cl. H01L 25/11; H01L 21/60

(52) U.S. Cl. 257/738; 257/777; 438/109; 257/E25.027; 257/E21.509

(57) ABSTRACT

There is provided a system and method for unpackaged and packaged IC stacked in a system-in-package module. There is provided a system-in-package module comprising a substrate including a first contact pad and a second contact pad disposed thereon, a packaged device disposed on the substrate, and an unpackaged device stacked atop the packaged device, wherein a first electrode of the packaged device is electrically and mechanically coupled to the first contact pad, and wherein a second electrode of the unpackaged device is electrically coupled to the second contact pad. The structure of the disclosed system-in-package module provides several advantages over conventional designs including increased yields, facilitated die substitution, enhanced thermal and grounding performance through direct connect vias, stacking of wider devices without a spacer, and a simplified single package structure for reduced fabrication time and cost.

### BACKGROUND OF THE INVENTION

1. Field of the Invention

The present invention relates generally to semiconductor devices. More particularly, the present invention relates to stacked packaging of semiconductor devices.

2. Background Art

System-in-chip or multi-chip package modules are often desirable in many circuit applications due to increased functionality, high performance, and compact form factor. When the semiconductor devices or integrated circuits (ICs) to be packaged are readily available as bare die, it is relatively straightforward to fabricate a single integrated system-in-chip or multi-chip package using existing techniques.

However, certain types of semiconductor devices are difficult to procure as bare unpackaged die. For example, memory chips may undergo a fabrication process where faulty die yields are discarded and only known working devices are embedded into individual packages before distribution. In another example, sensitive devices such as micro-electro-mechanical systems (MEMS) may only be available in packaged form for protection against environmental conditions and handling. It may be desirable to fabricate a single system-in-chip or multi-chip package integrating such packaged devices with other devices in bare die form, such as logic ICs.

Unfortunately, the packaged form factor of such packaged devices limits available design options for efficient integration with unpackaged devices. One approach is to place the packaged and unpackaged devices dies side-by-side on a shared package substrate. This approach undesirably increases lateral package form factor. Another approach is to place the unpackaged device into its own package and stacking the individual packages to form a composite module. However, by requiring at least two stacked packages rather than a single integrated package, this approach reduces thermal and electrical performance while increasing height, manufacturing cost and complexity.

Accordingly, there is a need to overcome the drawbacks and deficiencies in the art by providing a way to efficiently integrate packaged and unpackaged devices in a single package.

### SUMMARY OF THE INVENTION

There are provided systems and methods for unpackaged and packaged IC stacked in a system-in-package module, substantially as shown in and/or described in connection with at least one of the figures, as set forth more completely in the claims.

### BRIEF DESCRIPTION OF THE DRAWINGS

The features and advantages of the present invention will become more readily apparent to those ordinarily skilled in the art after reviewing the following detailed description and accompanying drawings, wherein:

FIG. 1A presents a cross sectional view of a packaged device and an unpackaged device;

FIG. 1B presents a cross sectional view of a conventional package-in-package module for integrating a packaged device and an unpackaged device;

FIG. 1C presents a cross sectional view of a conventional package-on-package module for integrating a packaged device and an unpackaged device;

FIGS. 2A, 2B, 2C, 2D and 2E present, in various stages of completion, cross sectional views of an exemplary system-in-package module for stacking a packaged device and an unpackaged device, according to embodiments of the present invention; and

FIG. 3 shows a flowchart describing the steps, according to one embodiment of the present invention, by which a system-in-package module for stacking a packaged device and an unpackaged device may be provided.

### DETAILED DESCRIPTION OF THE INVENTION

The present application is directed to a system and method for unpackaged and packaged IC stacked in a system-in-package module. The following description contains specific information pertaining to the implementation of the present invention. One skilled in the art will recognize that the present invention may be implemented in a manner different from that specifically discussed in the present application. Moreover, some of the specific details of the invention are not discussed in order not to obscure the invention. The specific details not described in the present application are within the knowledge of a person of ordinary skill in the art. The drawings in the present application and their accompanying detailed description are directed to merely exemplary embodiments of the invention. To maintain brevity, other embodiments of the invention, which use the principles of the present invention, are not specifically described in the present application and are not specifically illustrated by the present drawings.

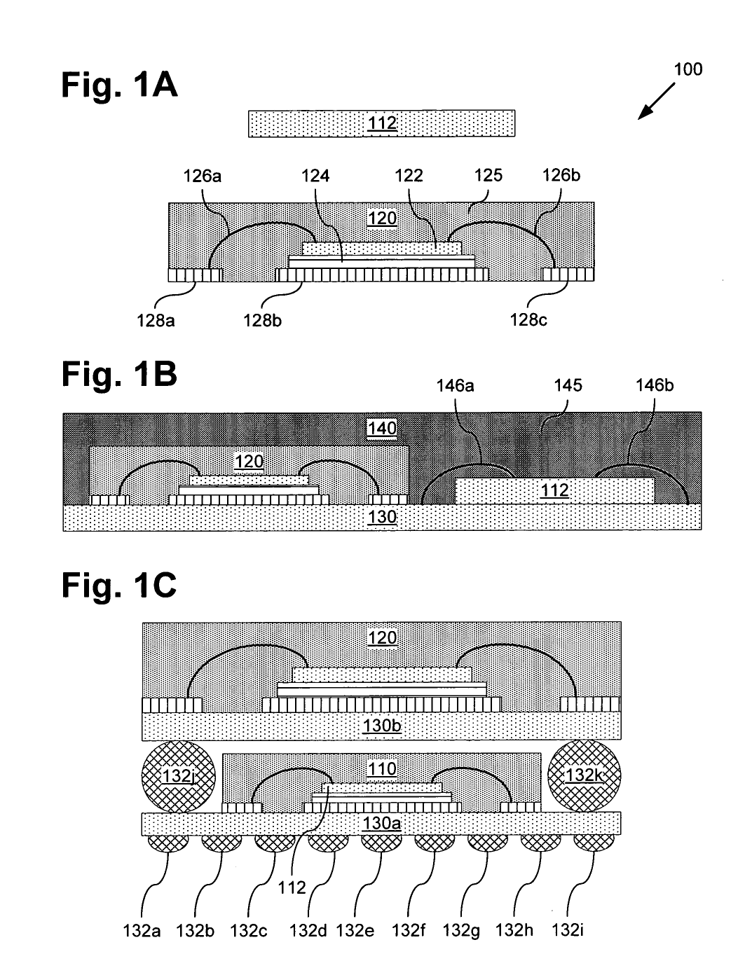

FIG. 1A presents a cross sectional view of a packaged device and an unpackaged device. Diagram 100 of FIG. 1A includes unpackaged device 112 and packaged device 120. Unpackaged device 112 may comprise, for example, a semiconductor device die such as a logic IC. Packaged device 120 may comprise, for example, a packaged memory chip, and may comprise semiconductor device die 122, adhesive 124, wirebonds 126a and 126b, and package terminals 128a, 128b, and 128c. Semiconductor device die 122 may comprise a memory chip IC. Adhesive 124 may comprise, for example, a conductive or insulating epoxy. Wirebonds 126a and 126b may comprise conventional gold or copper wirebonds or other attachment means such as metallic clips or ribbons.

As diagram 100 of FIG. 1A only shows packaged device 120 from a single cross sectional area, additional components may be present in packaged device 120 that are not specifically illustrated in FIG. 1A. For example, additional wirebonds and package terminals may be present at different depths of packaged device 120. For simplicity, these details have been omitted from the Figures and only cross-sectional views at a single depth will be shown. Furthermore, the elements in the Figures may not be drawn to scale to facilitate clarity and legibility.

Packaged device 120 may comprise various types of package configurations such as a leadless package including a quad flat no leads (QFN) package, a leaded package including a quad flat package (QFP), or another configuration such as a ball grid array (BGA) package. Thus, depending on the configuration of packaged device 120, package terminals 128a, 128b, and 128c may be directly soldered to a support surface or extended to solder balls or leads for external connection.

As previously discussed above, it may be desirable to integrate packaged device 120 with other bare dies such as unpackaged device 112. To this end, various conventional approaches have been attempted, but each approach has shown several drawbacks.

One such conventional approach is shown in FIG. 1B. FIG. 1B presents a cross sectional view of a conventional package-in-package module for integrating a packaged device and an unpackaged device. Diagram 100 of FIG. 1B includes package 140, which comprises packaged device 120 of FIG. 1A and unpackaged device 112 of FIG. 1A placed side by side on substrate 130 and encapsulated in mold compound 145. Wirebonds 146a and 146b connect electrodes of unpackaged device 112 to contact pads on substrate 130, omitted from FIG. 1B. In turn, traces within substrate 130, omitted from FIG. 1B, may electrically couple the contact pads to the bottom electrodes of packaged device 120 as necessary to complete the desired circuit, thereby connecting packaged device 120 and unpackaged device 112. Alternatively, traces in the receiving support board may provide the necessary connections. However, as seen in FIG. 1B, the lateral width of package 140 must be increased, disadvantageously enlarging the form factor of package 140.

Another conventional approach is shown in FIG. 1C. FIG. 1C presents a cross sectional view of a conventional package-on-package module for integrating a packaged device and an unpackaged device. Diagram 100 of FIG. 1C includes package 110, package 120, and solder balls 132a, 132b, 132c, 132d, 132e, 132f, 132g, 132h, 132i, 132j, and 132k. The structure of package 110 may correspond to the structure of packaged device 120 from FIG. 1A. Package 110 includes semiconductor device die 112, which may correspond to unpackaged device 112 from FIG. 1A. Package 120 may correspond to packaged device 120 from FIG. 1A. Package 110 and 120 are each mounted on a respective substrate 130a and 130b. Substrate 130a and 130b may each correspond to substrate 130 from FIG. 1B, and may more specifically comprise BGA substrates, with substrate 130a having solder balls 132a-132i attached and substrate 130b having solder balls 132j and 132k attached. In this manner, the unpackaged device 112 and the packaged device 120 from FIG. 1A may be integrated as a composite module. However, as seen in FIG. 1C, the height of the composite module is disadvantageously increased, the semiconductor device die 112 must be placed in its own package 110, and the complexity and cost is greatly increased compared to a single unified package.

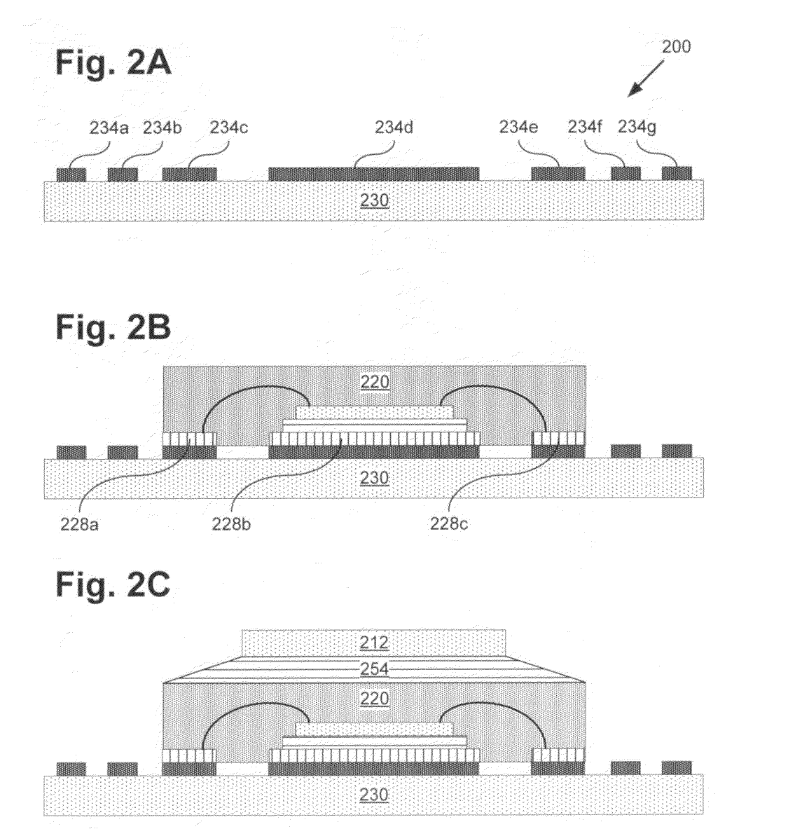

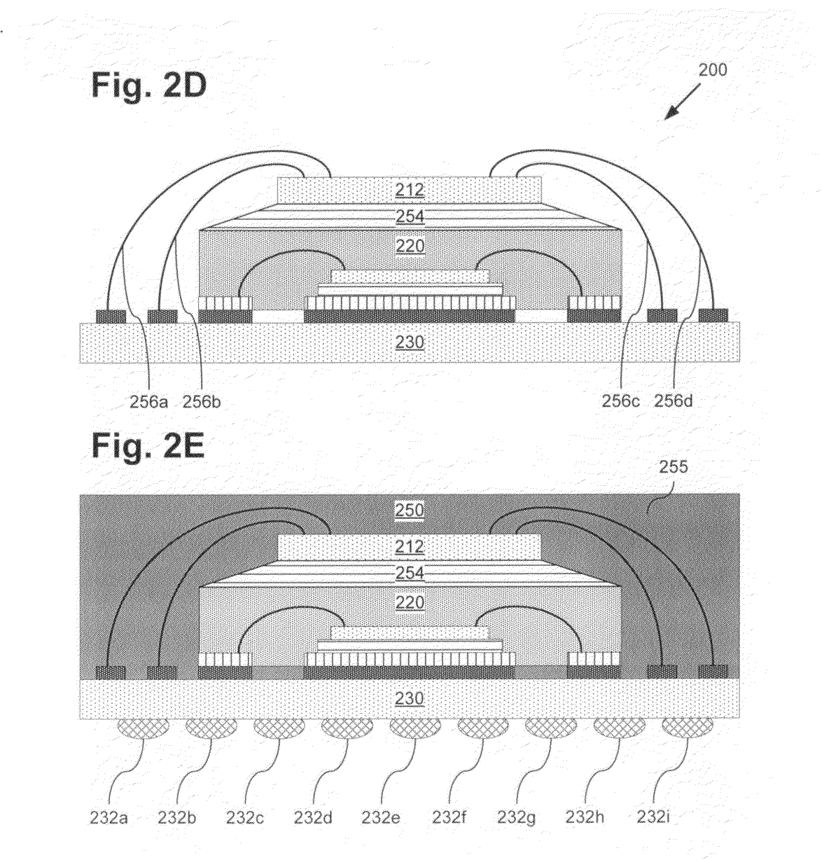

Thus, to avoid the problems associated with the above conventional designs, a novel system-in-package module including stacked unpackaged and packaged IC is disclosed below. FIGS. 2A, 2B, 2C, 2D and 2E present, in various stages of completion, cross sectional views of an exemplary system-in-package module for stacking a packaged device and an unpackaged device, according to embodiments of the present invention.

Starting with FIG. 2A, diagram 200 of FIG. 2A includes substrate 230 and contact pads 234a, 234b, 234c, 234d, 234e, 234f, and 234g. Substrate 230 may comprise any type of substrate such as a silicon substrate, a ceramic substrate, a direct bonded copper (DBC) substrate, a BGA substrate, or another type of substrate. Contact pads 234a through 234g may each comprise easily solderable materials such as nickel-palladium-gold (NiPdAu) tri-metals. While the cross sectional area shown in FIG. 2A is only large enough to accommodate a single system-in-package module, it is to be understood that substrate 230 may comprise part of a larger wafer (or strip) accommodating multiple system-in-package modules that are later singulated into individual devices.

Moving from FIG. 2A to FIG. 2B, package 220 is added to diagram 200 of FIG. 2B, wherein terminals of package 220 are soldered to contact pads 234c, 234d, and 234e on substrate 230. Thus, the contact pads 234c, 234d, and 234e are electrically and mechanically coupled respectively to the bottom electrodes or terminals 228a, 228b, and 228c of package 220. In alternative embodiments, different methods or materials may be utilized to attach package 220 to substrate 230, for example by using conductive adhesive. Package 220 may correspond to packaged device 120 from FIG. 1A.

Transitioning from FIG. 2B to FIG. 2C, unpackaged device 212 is added to diagram 200 of FIG. 2C, wherein unpackaged device 212 is affixed to the top surface of package 220 by adhesive 254. Unpackaged device 212 may correspond to unpackaged device 112 from FIG. 1A. Adhesive 254 may comprise, for example, conductive or insulating epoxy or solder. Additionally, other elements such as passive devices may be disposed on top of substrate 230, which are not shown in FIG. 2C.

Going from FIG. 2C to FIG. 2D, wirebonds 256a, 256b, 256c and 256d are attached to the top surface of unpackaged device 212 and are respectively connected to contact pads 234a, 234b, 234f, and 234g in diagram 200 of FIG. 2D. Thus, the top electrodes of unpackaged device 212 are electrically coupled to contact pads 234a, 234b, 234f, and 234g. As previously discussed, alternative attachment methods may also be utilized in lieu of wirebonding. Traces within substrate 230 or in a receiving support surface may then complete the necessary connections between unpackaged device 212, package 220, and any other included devices to connect the desired system-in-package circuit.

Shifting from FIG. 2D to FIG. 2E, mold compound 255 is added to encapsulate and form package 250 in diagram 200 of FIG. 2E. As shown in FIG. 2E, mold compound 255 fills the gaps under package 220 and surrounds wirebonds 256a through 256d. In alternative embodiments, package 250 may instead be hermetically sealed. Additionally, substrate 230 in FIG. 2E may more specifically comprise a BGA substrate, and solder bumps 232a, 232b, 232c, 232d, 232e, 232f, 232g, 232h, and 232i may be attached to the bottom of substrate 230. In alternative embodiments where package 250 may comprise a leaded or leadless package, substrate 230 may be attached to leads or attached directly to a support surface such as a printed circuit board (PCB). Finally, package 250 may be singulated if fabricated from a larger wafer, as previously discussed. Thus, a system-in-package module including stacked unpackaged and packaged IC has been provided.

The disclosed system-in-package module provides several advantages. First, because package 220 may be known as a tested working device, the assembly and final yields for package 250 may be improved. Second, because the form factor of package 220 may remain constant, die shrinks or substitutions of the device inside of it may be easily accommodated without changing substrate 230 or package 250 board design layouts. Third, because package 220 is closely coupled to the bottom of package 250, package 220 may be provided with enhanced thermal and grounding performance by connecting contact pads 234c, 234d, and 234e directly to thermal vias in the receiving support surface. Fourth, because package 220 is encapsulated within its own package, unpackaged device 212 may be stacked on top of package 220 without a spacer even if the width of unpackaged device 212 exceeds the width of package 220. Fifth, because package 250 is fabricated as a single integrated package, assembly is simplified and only a single metal finish is necessary for soldering and wirebonding, reducing fabrication time and costs while improving device performance and optimizing form factor. Thus, it can be seen that the disclosed system-in-package module including stacked unpackaged and packaged IC provides numerous advantages over conventional designs for integrating unpackaged and packaged IC.

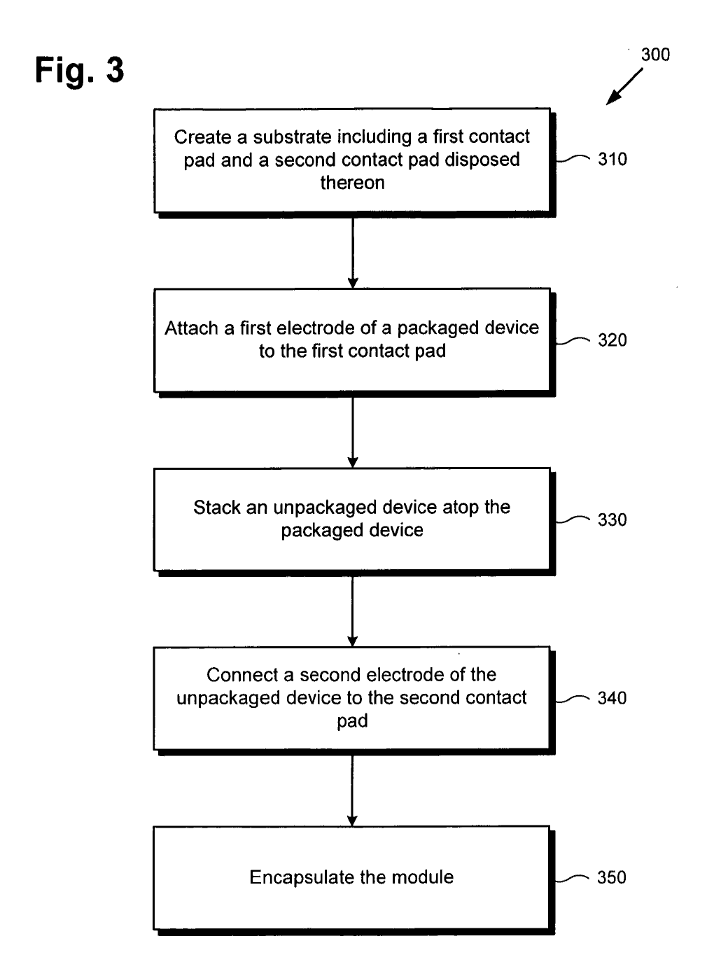

Turning to FIG. 3, FIG. 3 shows a flowchart describing the steps, according to one embodiment of the present invention, by which a system-in-package module for stacking a packaged device and an unpackaged device may be provided. Certain details and features have been left out of flowchart 300 that are apparent to a person of ordinary skill in the art. For example, a step may comprise one or more substeps or may involve specialized equipment or materials, as known in the art. While steps 310 through 350 indicated in flowchart 300 are sufficient to describe one embodiment of the present invention, other embodiments of the invention may utilize steps different from those shown in flowchart 300.

Referring to step 310 of flowchart 300 in FIG. 3 and diagram 200 of FIG. 2A, step 310 of flowchart 300 comprises creating substrate 230 including a first contact pad, or contact pad 234c, and a second contact pad, or contact pad 234b, disposed thereon. As previously discussed, substrate 230 may comprise any number of different substrate types, but for the present example it may be assumed that substrate 230 is a BGA substrate. Additionally, contact pads 234a, 234d, 234e, 234f, and 234g are also formed. Contact pads 234a through 234g may all be formed using a single metal finish and may comprise an easily solderable tri-metal such as NiPdAu, as previously described.

Referring to step 320 of flowchart 300 in FIG. 3 and diagram 200 of FIG. 2B, step 320 of flowchart 300 comprises attaching a first electrode, or terminal 228a, of packaged device 220 to the first contact pad created in step 310, or contact pad 234c. As previously discussed, the attachment may use solder, conductive adhesive, or another attachment means.

Referring to step 330 of flowchart 300 in FIG. 3 and diagram 200 of FIG. 2C, step 330 of flowchart 300 comprises stacking an unpackaged device 212 atop the packaged device 220 added in step 320. As shown in FIG. 2C, such a stacking may be effected using adhesive 254, which may comprise an adhesive epoxy that may be conductive or insulating. Additionally, as previously noted, since packaged device 220 is already in packaged form, the unpackaged device 212 may have a greater width than the packaged device 220 without adding an intermediate spacer.

Referring to step 340 of flowchart 300 in FIG. 3 and diagram 200 of FIG. 2D, step 340 of flowchart 300 comprises connecting a second electrode of the unpackaged device 212 stacked in step 330 to the second contact pad, or contact pad 234b formed in step 310. Thus, for example, wirebond 256b may be utilized to connect the second electrode on the top surface of unpackaged device 212 (not shown) to contact pad 234b. Additionally, wirebonds 256a, 256c, and 256d connect other electrodes of unpackaged device 212 to contact pads 234a, 234f, and 234g, respectively. As previously described, other attachment means besides wirebonds may also be utilized.

Referring to step 350 of flowchart 300 in FIG. 3 and diagram 200 of FIG. 2E, step 350 of flowchart 300 comprises encapsulating package 250. Thus, for example, a mold compound 255 may encapsulate the package 250. However, in alternative embodiments, the package 250 may be hermetically sealed. After step 350, additional steps may be carried out to extend connections from substrate 230. For example, since substrate 230 comprises a BGA substrate, a plurality of solder balls, or solder balls 232a through 232i, may be attached to the bottom of substrate 230 and connected to contact pads 234a through 234g through substrate 230. However, as previously discussed, alternative package configurations may connect to external leads or connect directly to a support surface. Finally, when the package is complete, it may be singulated from a larger wafer, as previously discussed. Thus, a method for providing a system-in-package module including stacked unpackaged and packaged IC has been disclosed

From the above description of the invention it is manifest that various techniques can be used for implementing the concepts of the present invention without departing from its scope. Moreover, while the invention has been described with specific reference to certain embodiments, a person of ordinary skills in the art would recognize that changes can be made in form and detail without departing from the spirit and the scope of the invention. As such, the described embodiments are to be considered in all respects as illustrative and not restrictive. It should also be understood that the invention is not limited to the particular embodiments described herein, but is capable of many rearrangements, modifications, and substitutions without departing from the scope of the invention.

1. A system-in-package module comprising:
a substrate including a first contact pad and a second contact pad disposed thereon;
a packaged device disposed on the substrate; and
an unpackaged device stacked atop the packaged device;
wherein a first electrode of the packaged device is electrically and mechanically coupled to the first contact pad, and wherein a second electrode of the unpackaged device is electrically coupled to the second contact pad.

2. The module of claim 1, wherein the unpackaged device is stacked atop the packaged device using an adhesive epoxy.

3. The module of claim 1, wherein the first electrode is soldered to the first contact pad.

4. The module of claim 1, wherein the second electrode is wirebonded to the second contact pad.

5. The module of claim 1, wherein the first contact pad and the second contact pad are electrically coupled through the substrate.

6. The module of claim 1, wherein the substrate is a ball grid array (BGA) substrate, and wherein the first contact pad and the second contact pad are electrically connected to a plurality of solder balls attached to a bottom of the substrate.

7. The module of claim 1, wherein a width of the unpackaged device is greater than a width of the packaged device.

8. The module of claim 1, wherein the packaged device is a memory chip.

9. The module of claim 1, further comprising a mold compound encapsulating the module.

10. The module of claim 1, wherein the first contact pad and the second contact pad comprise a single metal finish.

11-20. (canceled)
